(19) United States
(12) Patent Application Publication
(10) Pub. No.: US 2002/0067596 A1
(43) Pub. Date: Jun. 6, 2002

(54) Conduited heat dissipation device

(76) Inventors: Damion T. Searls, Portland, OR (US); Bin Lian, Hillsboro, OR (US); Prateek J. Dujari, Portland, OR (US); Terrance J. Dishongh, Hillsboro, OR (US)

Correspondence Address: Robert G. Winkle, BLAKELY, SOKOLOFF, TAYLOR & ZAFMAN, LLP, 7th Floor, 1240 Wilshire Boulevard, Los Angeles, CA, 90025, US

(21) Appl. No.: 09/730,629

(22) Filed: Dec. 5, 2000

(51) Int. Cl. H05K 7/20

(52) U.S. Cl. 361/695; 361/696

(57) ABSTRACT

A heat dissipation device that includes a conduit in a base portion thereof. An opening extends from a dissipation surface of the base portion to a conduit. The conduit allows air from a fan to flow within the base portion, which can improve heat removal from hotspots, and alleviate air stagnation in the heat dissipation device.

### BACKGROUND OF THE INVENTION

1. Field of the Invention

The present invention relates to apparatus and methods for removal of heat from electronic devices. In particular, the present invention relates to at least one conduit incorporated into a heat dissipation device for the removal of heat from a microelectronic die.

2. State of the Art

Higher performance, lower cost, increased miniaturization of integrated circuit components, and greater packaging density of integrated circuits are ongoing goals of the computer industry. As these goals are achieved, microelectronic dice become smaller. Accordingly, the density of power consumption of the integrated circuit components in the microelectronic die has increased, which, in turn, increases the average junction temperature of the microelectronic die. If the temperature of the microelectronic die becomes too high, the integrated circuits of the microelectronic die may be damaged or destroyed.

Various apparatus and techniques have been used and are presently being used for removing heat from microelectronic dice. One such heat dissipation technique involves the attachment of a high surface area heat sink to a microelectronic die. FIG. 4 illustrates an assembly 200 comprising a microelectronic die 202 (illustrated as a flip chip) physically and electrically attached to a substrate carrier 204 by a plurality of solder balls 206. A heat sink 208 is attached to a back surface 212 of the microelectronic die 202 by a thermally conductive adhesive 214. The heat sink 208 is usually constructed from a thermally conductive material, such as copper, copper alloys, aluminum, aluminum alloys, and the like. The heat generated by the microelectronic die 202 is drawn into the heat sink 208 (following the path of least thermal resistance) by conductive heat transfer.

High surface area heat sinks 208 are generally used because the rate at which heat is dissipated from a heat sink is substantially proportional to the surface area of the heat sink. The high surface area heat sink 208 usually includes a plurality of projections 216 extending substantially perpendicularly from the microelectronic die 202. It is, of course, understood that the projections 216 may include, but are not limited to, elongate planar fin-like structures and columnar/pillar structures. The high surface area of the projections 216 allows heat to be convectively dissipated from the projections 216 into the air surrounding the high surface area heat sink 208. A fan 218 may be incorporated into the assembly 200 to enhance the convective heat dissipation. However, although high surface area heat sinks are utilized in a variety of microelectronic applications, they have not been completely successful in removing heat from microelectronic dice that generate substantial amounts of heat.

One issue that may contribute to this lack of success is that the geometry of standard high surface area heat sinks results in an air stagnation zone over the center of the heat sink. Another issue that may contribute to this lack of success is the fact that high power circuits are generally located close to one another within the microelectronic dice 202. The concentration of the high power circuits results in areas of high heats or “hotspots”. Current heat sink solutions merely extract heat uniformly from the microelectronic die 202 and do not compensate for the hotspots. Thus, the circuitry at or proximate to these hotspots can be thermally damaged.

Therefore, it would be advantageous to develop apparatus and techniques to effectively remove heat from microelectronic dice while compensating for thermal variations, such as hot spots, within the microelectronic dice.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings to which:

FIG. 1 is a side cross-sectional view of a first embodiment of a heat dissipation device attached to a microelectronic die, according to the present invention;

FIG. 2 is an oblique view of the cross-sectional view of the heat dissipation device, according to the present invention;

FIG. 3 is a top plan view (without fins) of various conduit embodiments for a heat dissipation device, according to the present invention; and

FIG. 4 is a side cross-sectional view of a heat dissipation device attached to a microelectronic die, as known in the art.

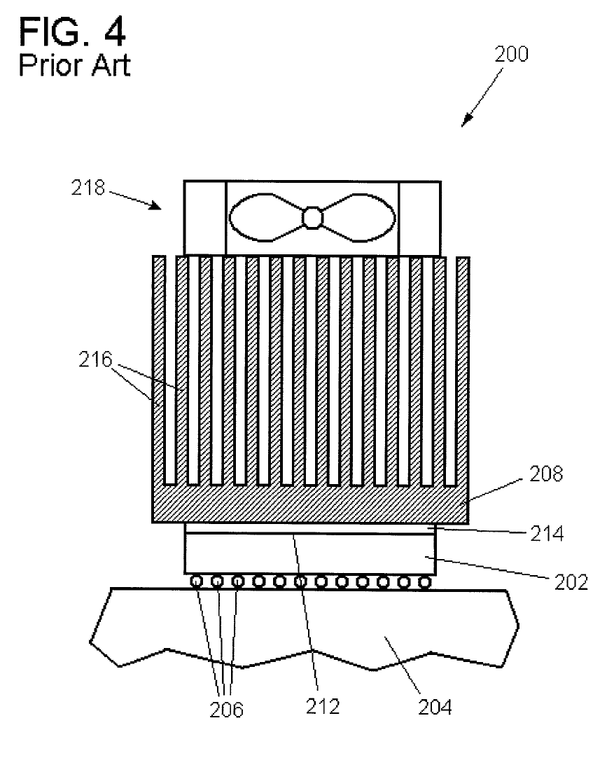

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable though skilled in the art to practice the invention. It is to be understood that the various embodiments of the invention, although different, are not necessarily mutually exclusive. For example, a particular feature, structure, or characteristic described herein, in connection with one embodiment, may be implement within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention comprises a heat dissipation device that includes at least one conduit in a base portion thereof. An opening extends from a dissipation surface of the base portion to a conduit. The conduit allows air from a fan to flow within the base portion, which can improve heat removal from hotspots, and alleviate air stagnation in the heat dissipation device.

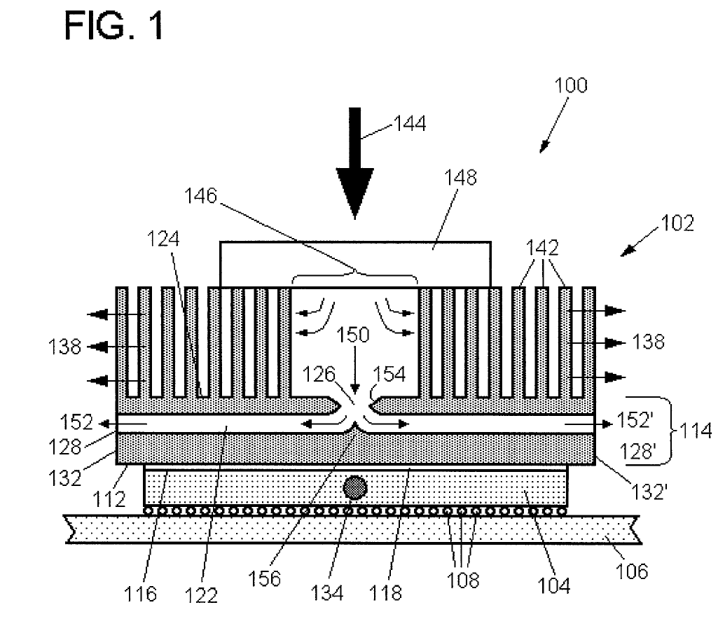

FIGS. 1 illustrates a microelectronic assembly 100 of the present invention comprising a heat dissipation device 102 attached to a microelectronic die 104 (illustrated as a flip chip). The microelectronic die 104 is physically and electrically attached to a substrate 106 by a plurality of solder balls 108. A mounting surface 112 of a base portion 114 of the heat dissipation device 102 is attached to a back surface 116 of the microelectronic die 104, preferably by a thermally conductive adhesive 118 as known in the art. Although the heat dissipation device 102 is illustrated as being attached to the microelectronic die 104, the invention is, of course, not so limited. The heat dissipation device 102 may be attached to any surface from which heat is desired to be dissipated. Furthermore, the heat dissipation device 102 is constructed from a thermally conductive material, such as copper, copper alloys, aluminum, aluminum alloys, and the like.

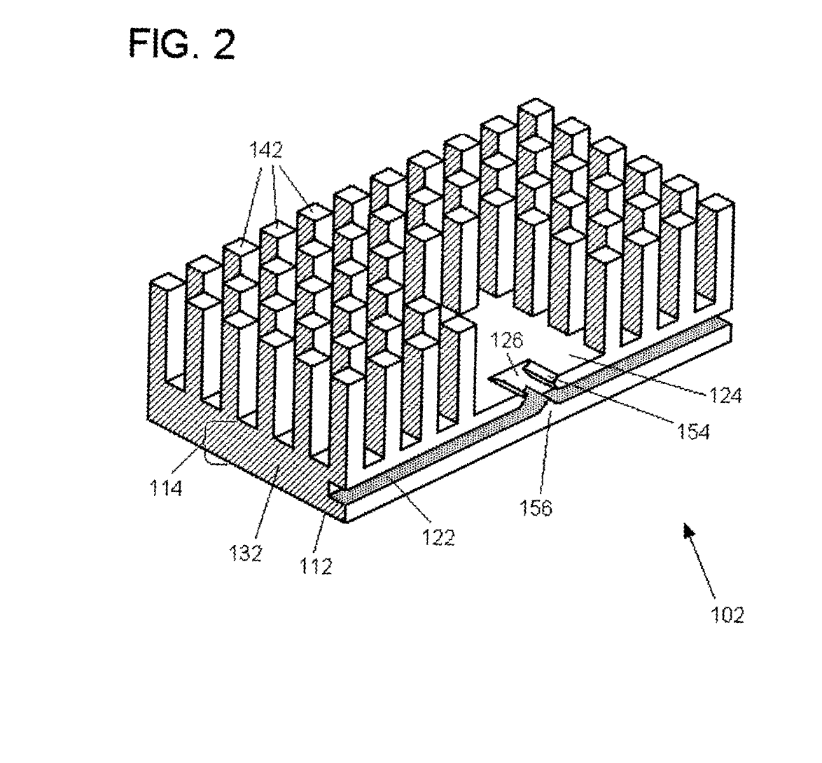

As shown in FIGS. 1 and 2, the heat dissipation device 102 comprises the base portion 114 with an air conduit 122 incorporated therein. The heat dissipation device 102 may be formed by any known technique, but is preferably formed by a molding process. The air conduit 122 may extend substantially parallel to the mounting surface 112 and an opposing dissipation surface 124 of the base portion 114. At least one opening 126 is formed from the base portion dissipation surface 124 to the air conduit 122. The air conduit 122 has at least one outlet (illustrated as outlets 128 and 128′ in FIG. 1) in at least one side (illustrated as 132 and 132′ in FIG. 1) of the base portion 114. The side(s) of said base portion 114 are illustrated as substantially perpendicular to the base portion dissipation surface 124. Referring to FIG. 1, the air conduit 122 is designed to assist in removing heat from at least one hotspot 134 within the microelectronic die 104. For sake of simplicity, the hotspot 134 is illustrated as a circle. Preferably, the air conduit opening 126 is positioned substantially over the hotspot 134. At minimum, the air conduit 122 should be placed proximate the hotspot 134.

The heat dissipation device 102 may include a plurality of projections 142 extending substantially perpendicularly from the base portion dissipation surface 124. The projections 142 are generally molded during the formation of the heat dissipation device 102 or machined therein after formation. It is, of course, understood that the projections 142 may include, but are not limited to, elongate planar fin-like structures (extending perpendicular to the figure) and columnar/pillar structures.

Referring to FIG. 1, air is blown in direction 144 (preferably substantially perpendicularly toward the air conduit opening 126) into the projections 142 and into an open area 146 in the projections 142 (surrounding the air conduit opening 126) by a fan 148 mounted adjacent the projections 142 (illustrated as mounted on the projections 142). Most of the air exits the projections 142 in a manner illustrated as direction 138. However, a portion of the air enters the air conduit opening 114 (shown as arrow 150) and exits the air conduits 128 and 128′ (shown by arrows 152 and 152′).

The air conduit opening 126 is shown with beveled edges 154 to assist in the flow of air into the air conduit 122. The air conduit 122 may also have a projection 156 disposed therein which is under the air conduit opening 126 to assist in directing the air entering the air conduit 122. The air conduit opening 126 is also illustrated as being formed in a central portion of the air conduit 122 under the fan 148. As an air stagnation zone may form under the fan 148 in conventional design, the design illustrated alleviates the stagnation zone with the placement of the air conduit opening 126. Further, the heat dissipation device 102 can convectively transfer more heat into the air in the air conduit 122 than it can over the base portion dissipation surface 124. It is, of course, understood that a design guideline is to achieve maximum airflow to the hotspot 134 while minimizing conduction loss due to the loss of thermally conductive material from the base portion 114.

It is understood that the air conduit designs of the present invention may take on a variety of configurations. For example, the air conduit 122 of the present invention is shown as having a substantially square cross-sectional shape. However, the air conduit 122 may have any appropriate cross-sectional shape including, but not limited to, circular, oval, triangular, rectangular, and the like.

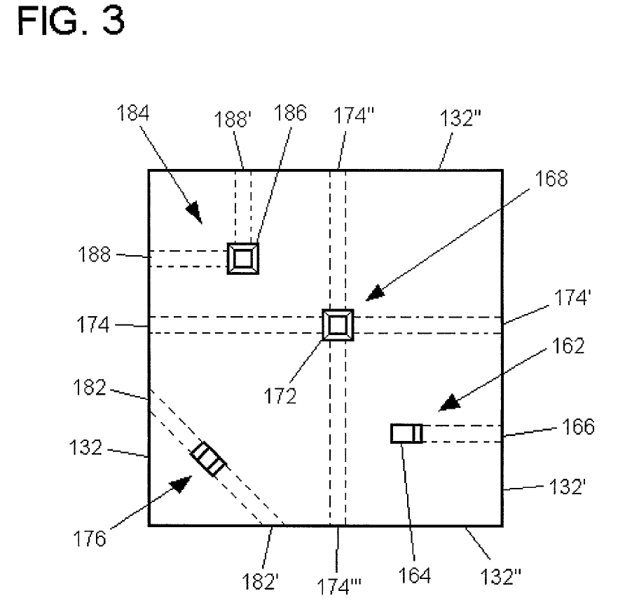

Furthermore, the air conduits 122 may take on any direction or configuration, as shown in FIG. 3 which is a plan view of the base portion dissipation surface 124 without the projections 142. An air conduit 162 may have an opening 164 and a single outlet 166. An air conduit may have multiple outlets as shown with air conduit 168 which has an opening 172 and four outlets 174, 174′, 174″, and 174′″ which exit on sides 132, 132′, 132″, and 132′″, respectively. An air conduit may not necessary run parallel to a base portion side. A conduit may run diagonally and any angle as shown with air conduit 176 that has an opening 178 and two outlets 182 and 182′. The air conduits preferably follow a path of minimum distance to a base portion side, such as shown with air conduit 184 that has an opening 186 and two outlets 188 and 188′ which are substantially perpendicular to one another.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A heat dissipation device, comprising:
a base portion having at least one conduit defined therein, said base portion having a dissipation surface;
said at least one conduit having at least one outlet on at least one side of said base portion; and
at least one conduit opening extending from said base portion dissipation surface to said at least one conduit.

2. The heat dissipation device of claim 1, further including a fan positioned to blow air substantially toward said conduit opening.

3. The heat dissipation device of claim 1, further including a plurality of projections extending from said base portion dissipation surface.

4. The heat dissipation device of claim 3, wherein said plurality of projections extends substantially perpendicularly to said base portion dissipation surface.

5. The heat dissipation device of claim 3, further including a fan mounted on at least a portion of said projections to blow air substantially toward said conduit opening.

6. The heat dissipation device of claim 1, wherein said conduit comprises a plurality of said outlets.

7. A microelectronic assembly, comprising:
a microelectronic die having a back surface; and
a heat dissipation device, comprising:
a base portion having at least one conduit defined therein, said base portion having a dissipation surface;
said at least one conduit having at least one outlet on at least one side of said base portion; and
at least one conduit opening extending from said base portion dissipation surface to said at least one conduit.

8. The microelectronic assembly of claim 7, wherein said heat dissipation device further includes a fan positioned to blow air substantially toward said conduit opening.

9. The microelectronic assembly of claim 7, wherein said heat dissipation device further includes a plurality of projections extending from said base portion dissipation surface.

10. The microelectronic assembly of claim 9, wherein said plurality of projections extends substantially perpendicularly from said base portion dissipation surface.

11. The microelectronic assembly of claim 9, further including a fan mounted on at least a portion of said plurality of projections to blow air substantially toward said conduit opening.

12. The microelectronic assembly of claim 7, wherein said conduit comprises a plurality of said outlets.

13. The microelectronic assembly of claim 7, wherein said conduit is positioned proximate a hotspot within said microelectronic device.

14. The microelectronic assembly of claim 7, wherein said conduit opening is positioned proximate a hotspot within said microelectronic device.

15. A method of cooling a microelectronic die, comprising:
providing a heat dissipation device, comprising:
a base portion having at least one conduit defined therein, said base portion having a dissipation surface;
said at least one conduit having at least one outlet on at least one side of said base portion; and
at least one conduit opening extending from said base portion dissipation surface to said at least one conduit;
attaching said heat dissipation device to a back surface of said microelectronic die; and
forcing air into said at least one conduit opening, such that air flows through said at least one conduit to exit said at least one conduit outlet.

16. The method of claim 15, wherein forcing air into said at least one conduit opening comprises providing a fan positioned to blow air substantially toward the conduit opening and activating said fan.

17. The method of claim 15, wherein providing said heat dissipation device further includes providing said heat dissipation device having a plurality of projections extending from said base portion dissipation surface.

18. The method of claim 17, wherein providing said heat dissipation device having a plurality of projections further includes providing said heat dissipation device wherein said plurality of projections extend substantially perpendicularly from said base portion dissipation surface.

19. The method of claim 17, wherein forcing air into said at least one conduit opening comprises providing a fan mounted to at least a portion of said plurality of projections to blow air substantially toward said conduit opening and activating said fan.

20. The method of claim 15, wherein providing said heat dissipation device further includes providing said heat dissipation device having a plurality of conduit outlets.

21. The method of claim 15, further including positioning said heat dissipation device on said microelectronic device such that said conduit is positioned proximate a hotspot within said microelectronic device.

22. The method of claim 15, further including positioning said heat dissipation device on said microelectronic device such that said conduit opening is positioned proximate a hotspot within said microelectronic device.
